(19) United States
(12) Patent Application Publication
(10) Pub. No.: US 2007/0119376 A1
(43) Pub. Date: May 31, 2007

(54) Matching device and plasma processing apparatus

(75) Inventors: Nobuo Ishii, Hyogo (JP); Kibatsu Shinohara, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Tokyo Electron Limited and Nihon Koshuha Co., Ltd.

(21) Appl. No.: 11/657,531

(22) Filed: Jan. 25, 2007

Related U.S. Application Data
(62) Division of application No. 10/491,212, filed on Mar. 26, 2004.

(30) Foreign Application Priority Data
Sep. 28, 2001 (JP) 2001-300406

(51) Int. Cl. C23F 1/00; C23C 16/00

(52) U.S. Cl. 118/723 MW; 156/345.41

(57) ABSTRACT

A machining device includes first branched waveguides (71A-71C) and second branched waveguides (73A-73C) connected perpendicularly to an axial (Z) direction of a cylindrical waveguide (14) and having one end which opens in the cylindrical waveguide (14) and the other end which is electrically short-circuited. The first branched waveguides (71A-71C) are arranged at a predetermined interval in an axial (z) direction of the cylindrical waveguide (14). The second branched waveguides (73A-73C) are arranged in positions which make an angle of 90° with positions of the first branched waveguides (71A-71C) when viewed from the axis (Z) of the cylindrical waveguide (14), and arranged at a predetermined interval in the axial (Z) direction of the cylindrical waveguide (14). With this arrangement, it is possible to accurately and easily control the impedance matching between the supply side and load side of the cylindrical waveguide (14).

### BACKGROUND ART

The present invention relates to a matching device and, more particularly, to a matching device for matching the impedances of the supply side and load side of a cylindrical waveguide.

The present invention also relates to a plasma processing apparatus and, more particularly, to a plasma processing apparatus for generating a plasma by using a high-frequency electromagnetic field, and processing an object to be processed such as a semiconductor or LCD (Liquid Crystal Display).

In the fabrication of semiconductor devices and flat panel displays, plasma processing apparatuses are often used to form oxide films and perform crystal growth, etching, and ashing of semiconductor layers. One of these plasma processing apparatuses is a microwave plasma processing apparatus which generates a plasma by supplying a microwave from a radial line slot antenna (to be abbreviated as an RLSA hereinafter) into a processing vessel, and ionizing and dissociating a gas in the processing vessel by the action of the electromagnetic field of the microwave. This microwave plasma processing apparatus can generate a high-density plasma at a low pressure, and hence can perform efficient plasma processing.

Some microwave plasma processing apparatuses use a method which supplies a circularly polarized wave to the RLSA via a cylindrical waveguide. A circularly polarized wave is an electromagnetic wave which is a rotating electric field whose field vector rotates once in one period in a plane perpendicular to the direction of travel. Accordingly, when this circularly polarized wave is supplied, the field strength distribution in the RLSA becomes symmetric with respect to the axis of the traveling direction of the circularly polarized wave on time average. This makes it possible to supply a microwave having the time-average, axially symmetric distribution from the RLSA into the processing vessel, and generate a highly uniform plasma by the action of the electromagnetic field of the microwave.

Unfortunately, if the microwave is reflected in the processing vessel or RLSA, enters the cylindrical waveguide form the RLSA, and is reflected again, the axial ratio of the circularly polarized wave increases by the influence of this reflection. This decreases the axial symmetry of the field strength distribution (time average) in the RLSA. The axial ratio is the ratio of the maximum value to the minimum value in the field strength distribution (time average) on the circular section of the circularly polarized wave. The axial ratio of the circularly polarized wave is desirably close to 1. Therefore, a technique which reduces the reflected wave propagating in the cylindrical waveguide by attaching a matching device to the cylindrical waveguide is proposed. This technique will be explained below.

FIG. 18 is a view for explaining the conventional matching device. That is, FIG. 18 shows a sectional arrangement including the axis (Z) of a cylindrical waveguide having the matching device. FIG. 19 is a sectional view, taken along a line XIX-XIX′ in FIG. 18, showing the sectional arrangement of the matching device in a plane (X-Y plane) perpendicular to the axis (Z) of the cylindrical waveguide.

A matching device 1017 shown in FIGS. 18 and 19 is a matching device for a cylindrical waveguide 1014 in which a TE₁₁-mode circularly polarized wave propagates. A plurality of stabs project in the radial direction from the inner wall surface of the cylindrical waveguide 1014. More specifically, three stabs 1071A to 1071C are equally spaced in the direction of the axis (Z) of the cylindrical waveguide 1014, three stabs 1072A to 1072C oppose the three stabs 1071A to 1071C, three stabs 1073A to 1073C are arranged in positions rotated 90°, from the positions of the three stabs 1071A to 1071C, in the circumferential direction around the axis of the cylindrical waveguide 1014, and three stabs 1074A to 1074C (stabs 1074B and 1074C are not shown) oppose the three stabs 1073A to 1073C. In the coordinate system, the stabs 1071A to 1071C and stabs 1072A to 1072C oppose each other in the X-Z plane, and the stabs 1073A to 1073C and stabs 1074A to 1074C oppose each other in the Y-Z plane. The stabs 1071A to 1074C are metal rods having a circular section. The reactance of the stabs 1071A to 1074C changes in accordance with the length of projection, i.e., the length the stabs project in the radial direction from the inner wall surface of the cylindrical waveguide 1014, thereby changing the reactance of the cylindrical waveguide 1014.

An RLSA 1015 is connected to the load side of the cylindrical waveguide 1014 having the matching device 1017. The supply side of the cylindrical waveguide 1014 is connected to a high-frequency power supply 1011 for generating a microwave, a circularly polarized wave converter 1016 for converting the microwave into a circularly polarized wave, and a detector 1018 for detecting the internal voltage of the cylindrical waveguide 1014. The detector 1018 is connected to a controller 1020 which calculates the impedance of the load side on the basis of an output signal from the detector 1018, and calculates the projection length of the stabs 1071A to 1071C, which satisfies the impedance matching conditions between the supply side and load side. The controller 1020 is connected to a driver 1019 which adjusts the projection length of the stabs 1071A to 1071C of the matching device 1017 in accordance with instructions from the controller 1020.

In this arrangement, to match the impedances of the supply side and load side of the cylindrical waveguide 1014, a reflected wave from the RLSA 1015 is canceled by a reflected wave of the matching device 1017, thereby reducing a reflected wave propagating in the cylindrical waveguide 1014. Consequently, the field strength distribution in the RLSA 1015 becomes a time-average, axially symmetric distribution, so a highly uniform plasma can be generated.

In the conventional matching device 1017, however, if the projection length of the stabs 1071A to 1071C is increased, the proportional relationship between the projection length and reactance of the stabs 1071A to 1074C is lost. That is, as shown in FIG. 20, when the projection length of the stabs 1071A to 1071C and 1072A to 1072C in the X-Z plane and the projection length of the stabs 1073A to 1073C and 1073A to 1073C in the Y-Z plane are equally changed, the reactance changes substantially linearly with the projection length if the projection length is L₀ or less, but the reactance increases exponentially with the projection length if the projection length exceeds L₀. This is presumably because when the projection length increases and the distance between the stabs 1071A to 1071C and 1072A to 1072C in the X-Z plane and the stabs 1073A to 1073C and 1074A to 1074C in the Y-Z plane decreases, the former and latter interfere with each other and increase the reactance. This increase in reactance changes in accordance with various conditions such as the frequency of the microwave.

Accordingly, if the reflected wave is large and it is necessary to increase the reactance by increasing the projection length of the stabs 1071A to 1074C, the matching device 1017 is difficult to accurately control by taking account of even the increase in reactance.

As a consequence, if the reflected wave is large, it is difficult to reduce this reflected wave by the matching device 1017 and generate a highly uniform plasma.

### DISCLOSURE OF INVENTION

The present invention has been made to solve the above problems, and has as its object to provide a matching device capable of easily performing accurate control.

It is another object of the present invention to provide a plasma processing apparatus capable of easily generating a highly uniform plasma.

To achieve the above objects, a matching device of the present invention is characterized by comprising a plurality of first branched waveguides connected perpendicularly to an axial direction of a cylindrical waveguide or coaxial waveguide, and having one end which opens in the cylindrical waveguide or in an outer conductor of the coaxial waveguide and the other end which is electrically functionally short-circuited, wherein the first branched waveguides are arranged at a predetermined interval in the axial direction of the cylindrical waveguide or coaxial waveguide.

This matching device may further comprise a plurality of second branched waveguides connected perpendicularly to the axial direction of the cylindrical waveguide or coaxial waveguide, and having one end which opens in the cylindrical waveguide or in the outer conductor of the coaxial waveguide and the other end which is electrically functionally short-circuited, wherein the second branched waveguides are arranged in positions which make an angle of 90° with positions of the first branched waveguides when viewed from an axis of the cylindrical waveguide or coaxial waveguide, and arranged at a predetermined interval in the axial direction of the cylindrical waveguide or coaxial waveguide.

The matching device may further comprise a plurality of third branched waveguides connected perpendicularly to the axial direction of the cylindrical waveguide or coaxial waveguide, and having one end which opens in the cylindrical waveguide or in the outer conductor of the coaxial waveguide and the other end which is electrically functionally short-circuited, wherein the third branched waveguides oppose the first branched waveguides.

The matching device may further comprise a plurality of third branched waveguides and a plurality of fourth branched waveguides connected perpendicularly to the axial direction of the cylindrical waveguide or coaxial waveguide, and having one end which opens in the cylindrical waveguide or in the outer conductor of the coaxial waveguide and the other end which is electrically functionally short-circuited, wherein the third branched waveguides oppose the first branched waveguides, and the fourth branched waveguides oppose the second branched waveguides.

In the above matching device, the number of the branched waveguides arranged in the axial direction of the cylindrical waveguide or coaxial waveguide may be at least three.

In particular, an interval between the branched waveguides in the axial direction of the cylindrical waveguide or coaxial waveguide may be ¼ or ⅛ a guide wavelength of the cylindrical waveguide or coaxial waveguide.

Also, all intervals between the branched waveguides arranged in the axial direction of the cylindrical waveguide or coaxial waveguide may be equal or different.

In the above matching device, the first and second branched waveguides may be alternately arranged in the axial direction of the cylindrical waveguide or coaxial waveguide.

Alternatively, all the first branched waveguides and all the second branched waveguides may be arranged in different regions in the axial direction of the cylindrical waveguide or coaxial waveguide.

The above matching device may also have an arrangement in which a short-circuit plate which. electrically functionally short-circuits the other end of the branched waveguide is slidable in the branched waveguide.

The matching device may further comprise detecting means for detecting an internal voltage of the cylindrical waveguide or coaxial waveguide, and control means for sliding the short-circuit plate of the branched waveguide on the basis of an output signal from the detecting means.

A matching device of the present invention is characterized by comprising a plurality of first stabs and a plurality of second stabs which project in a radial direction from an inner wall surface of a cylindrical waveguide or from an inner wall surface of an outer conductor of a coaxial waveguide, wherein the first stabs are arranged at a predetermined interval in an axial direction of the cylindrical waveguide or coaxial waveguide, the second stabs are arranged in positions which make an angle of 90° with positions of the first stabs when viewed from an axis of the cylindrical waveguide or coaxial waveguide, and arranged at a predetermined interval in the axial direction of the cylindrical waveguide or coaxial waveguide, and the first and second stabs are arranged in different planes perpendicular to the axis of the cylindrical waveguide or coaxial waveguide.

The first and second stabs may be alternately arranged in the axial direction of the cylindrical waveguide or coaxial waveguide.

Also, all the first stabs and all the second stabs may be arranged in different regions in the axial direction of the cylindrical waveguide or coaxial waveguide.

These matching devices may further comprise a plurality of third stabs and a plurality of fourth stabs which project in the radial direction from the inner wall surface of the cylindrical waveguide or from the inner wall surface of the outer conductor of the coaxial waveguide, wherein the third stabs oppose the first stabs, and the fourth stabs oppose the second stabs.

A matching device of the present invention is characterized by comprising a plurality of first stabs and a plurality of second stabs which project in a radial direction from an inner wall surface of a cylindrical waveguide or from an inner wall surface of an outer conductor of a coaxial waveguide, wherein the first stabs are arranged at a predetermined interval in an axial direction of the cylindrical waveguide or coaxial waveguide, the second stabs are arranged in positions which make an angle of 90° with positions of the first stabs when viewed from an axis of the cylindrical waveguide or coaxial waveguide, and arranged at a predetermined interval in the axial direction of the cylindrical waveguide or coaxial waveguide, and at least tips of the first and second stabs are made of a dielectric material having a relative dielectric constant of 1 or more.

This matching device may further comprise a plurality of third stabs and a plurality of fourth stabs which project in the radial direction from the inner wall surface of the cylindrical waveguide or from the inner wall surface of the outer conductor of the coaxial waveguide, wherein the third stabs oppose the first stabs, the fourth stabs oppose the second stabs, and at least tips of the first and second stabs are made of a dielectric material having a relative dielectric constant of 1 or more.

In the above matching device using the stabs, the number of the stabs arranged in the axial direction of the cylindrical waveguide or coaxial waveguide may be at least three.

In particular, an interval between the stabs in the axial direction of the cylindrical waveguide or coaxial waveguide may be ¼ or ⅛ a guide wavelength of the cylindrical waveguide or coaxial waveguide.

Also, all intervals of the stabs arranged in the axial direction of the cylindrical waveguide or coaxial waveguide may be equal or different.

The above matching device using the stabs may also have an arrangement in which a projection length, which is a length of projection from the inner wall surface of the cylindrical waveguide or from the inner wall surface of the outer conductor of the coaxial waveguide, of the stabs is changeable.

The matching device may further comprise detecting means for detecting an internal voltage of the cylindrical waveguide or coaxial waveguide, and control means for changing the projection length of the stabs on the basis of an output signal from the detecting means.

In all the matching devices described above, a TE₁₁-mode circularly polarized wave electromagnetic field may propagate in the cylindrical waveguide, and a TE-mode rotating electromagnetic field may propagate in the coaxial waveguide.

To achieve the above objects, a plasma processing apparatus of the present invention is characterized by comprising a processing vessel which accommodates an object to be processed such as a semiconductor or LCD, a slot antenna which supplies an electromagnetic field into the processing vessel, a cylindrical waveguide or coaxial waveguide connected between the slot antenna and a high-frequency power supply, and a matching device attached to the cylindrical waveguide or coaxial waveguide to match impedances of the slot antenna and power supply, wherein the above-mentioned matching device is used as the matching device.

To achieve the above objects, a plasma processing apparatus of the present invention comprising a processing vessel which accommodates an object to be processed, a magnetic field generator which generates a magnetic field in the vessel, and a cylindrical waveguide or coaxial waveguide which supplies a microwave into the vessel, the plasma processing apparatus generating a plasma by using electrons heated by electron-cyclotron resonance, characterized by comprising the matching device described above.

### BRIEF DESCRIPTION OF DRAWINGS

FIG. 1 is a sectional view showing the arrangement of a processing vessel of a plasma processing apparatus according to the first embodiment of the present invention;

FIG. 2 is a view showing the mechanical arrangement of an electromagnetic field supply apparatus of the plasma processing apparatus according to the first embodiment of the present invention;

FIG. 3 is a view for explaining a matching device and detector of the electromagnetic field supply apparatus.

FIG. 4 is a sectional view taken along a line IV-IV′ in FIG. 2;

FIG. 5 is a sectional view taken along a line V-V′ in FIG. 2;

FIG. 6 is a block diagram showing the configuration of a control system of the electromagnetic field supply apparatus;

FIGS. 7A to 7E are views showing the sectional shapes of branched waveguides of the matching device;

FIGS. 8A and 8B are perspective views showing examples of the arrangement of a short-circuit plate of the branched waveguide;

FIG. 9A is a graph showing the voltage distribution in a plane perpendicular to the axis of a cylindrical waveguide having no matching device, when an output microwave from a high-frequency power supply is converted into a circularly polarized wave and supplied to a radial line slot antenna via the cylindrical waveguide, and FIG. 9B is a graph showing the voltage distribution in the plane perpendicular to the axis of a cylindrical waveguide having a matching device, when the output microwave from the high-frequency power supply is converted into a circularly polarized wave and supplied to the radial line slot antenna via the cylindrical waveguide;

FIG. 10A is a sectional view showing the arrangement of a matching device according to the second embodiment of the present invention, and FIG. 10B is a sectional view taken along a line Xb-Xb′ in FIG. 10A;

FIG. 11 is a sectional view showing the arrangement of a matching device according to the third embodiment of the present invention;

FIG. 12 is a sectional view taken along a line XII-XII′ in FIG. 11;

FIG. 13A is a sectional view showing the arrangement of a matching device according to the fourth embodiment of the present invention, and FIG. 13B is a sectional view taken along a line XIIIb-XIIIb′ in FIG. 13A;

FIG. 14 is a sectional view showing the arrangement of a processing vessel of a plasma processing apparatus according to the fifth embodiment of the present invention;

FIG. 15 is a view showing the mechanical arrangement of an electromagnetic field supply apparatus of the plasma processing apparatus according to the fifth embodiment of the present invention;

FIG. 16 is a view showing an example of the arrangement of an ECR plasma processing apparatus according to the sixth embodiment of the present invention;

FIG. 17 is a view showing another example of the arrangement of the ECR plasma processing apparatus according to the sixth embodiment of the present invention;

FIG. 18 is a view for explaining the conventional matching device;

FIG. 19 is a sectional view taken along a line XIX-XIX′ in FIG. 18; and

FIG. 20 is a graph showing the relationship between the projection length and reactance of stabs in the conventional matching device.

### DETAILED DESCRIPTION OF EMBODIMENTS

Embodiments of the present invention will be described below with reference to the accompanying drawings.

### First Embodiment

A plasma processing apparatus using a matching device of the present invention has a processing vessel which accommodates an object to be processed and performs plasma processing for this object, and an electromagnetic field supply apparatus which supplies a microwave into this processing vessel and generates a plasma in the processing vessel by the action of the electromagnetic field of the microwave. The arrangements of the processing vessel and electromagnetic field supply apparatus of the plasma processing apparatus of the first embodiment of the present invention will be separately described below.

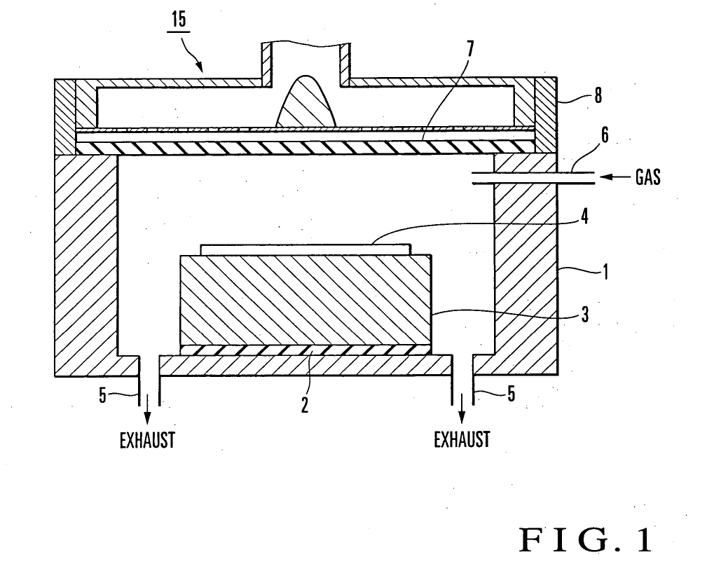

FIG. 1 is a sectional view showing the arrangement of the processing vessel.

A processing vessel 1 has a closed-end cylindrical shape having an open upper portion. A substrate table 3 is fixed via an insulating plate 2 to a central portion of the bottom surface of the processing vessel 1. On the upper surface of the substrate table 3, a substrate 4, such as a semiconductor or LCD, as an object to be processed is placed. Exhaust ports 5 for evacuation are formed in the periphery of the bottom surface of the processing vessel 1. A gas supply nozzle 6 for supplying gases into the processing vessel 1 is formed in the circumferential wall of the processing vessel 1. When this plasma processing apparatus is used as an etching apparatus, for example, the nozzle 6 supplies a plasma gas such as Ar and an etching gas such as CF₄.

The upper opening of the processing vessel 1 is closed with a dielectric plate 7 so as to prevent a leak of the plasma to the outside. On the dielectric plate 7, a radial line slot antenna (to be abbreviated as an RLSA hereinafter) 15 of the electromagnetic field supply apparatus is mounted. The RLSA 15 is isolated from the processing vessel 1 by the dielectric plate 7 and thereby protected from the plasma generated in the processing vessel 1. The outer circumferential surfaces of the dielectric plate 7 and RLSA 15 are covered with a shield member 8 placed annularly on the circumferential wall of the processing vessel 1, thereby preventing a leak of the microwave to the outside.

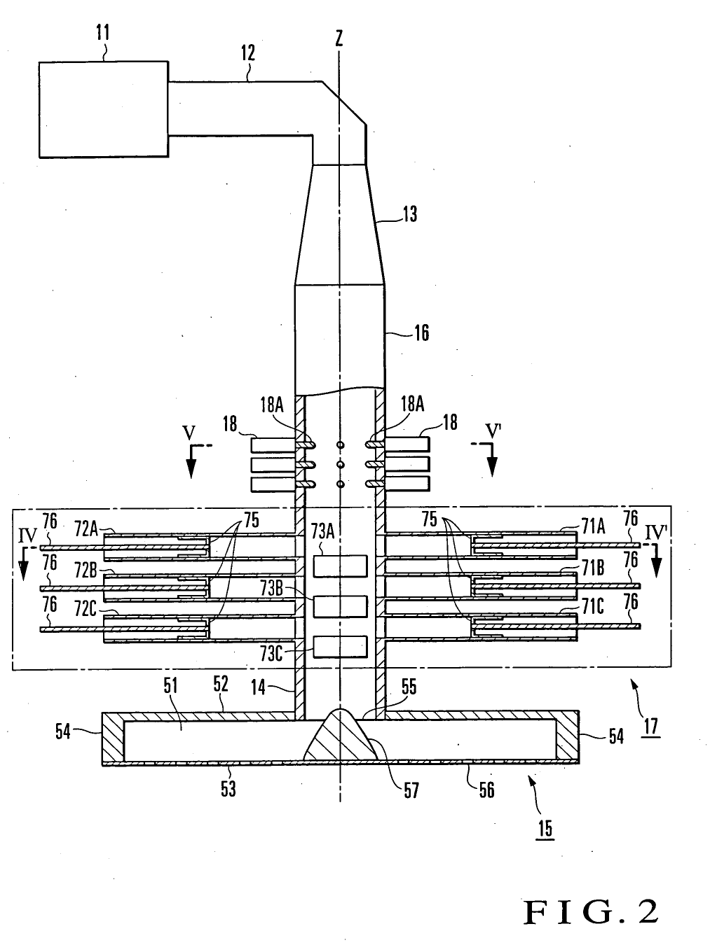

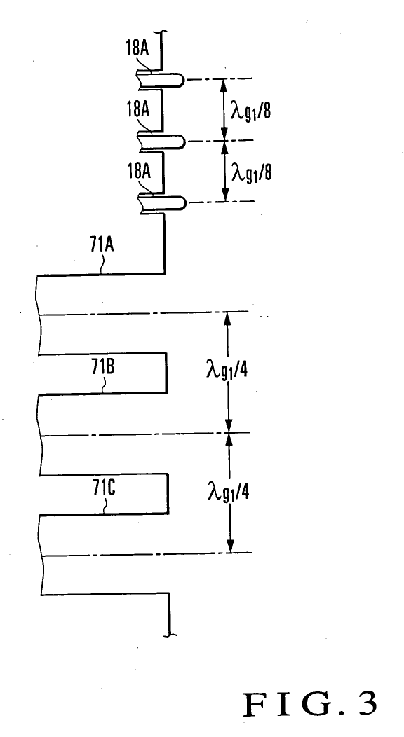

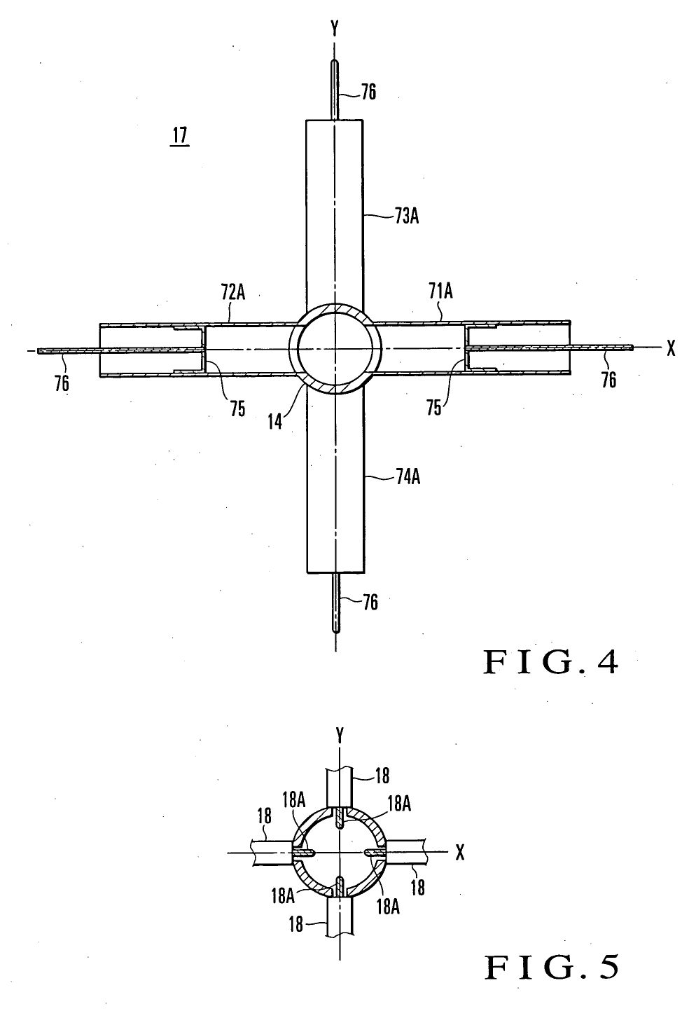

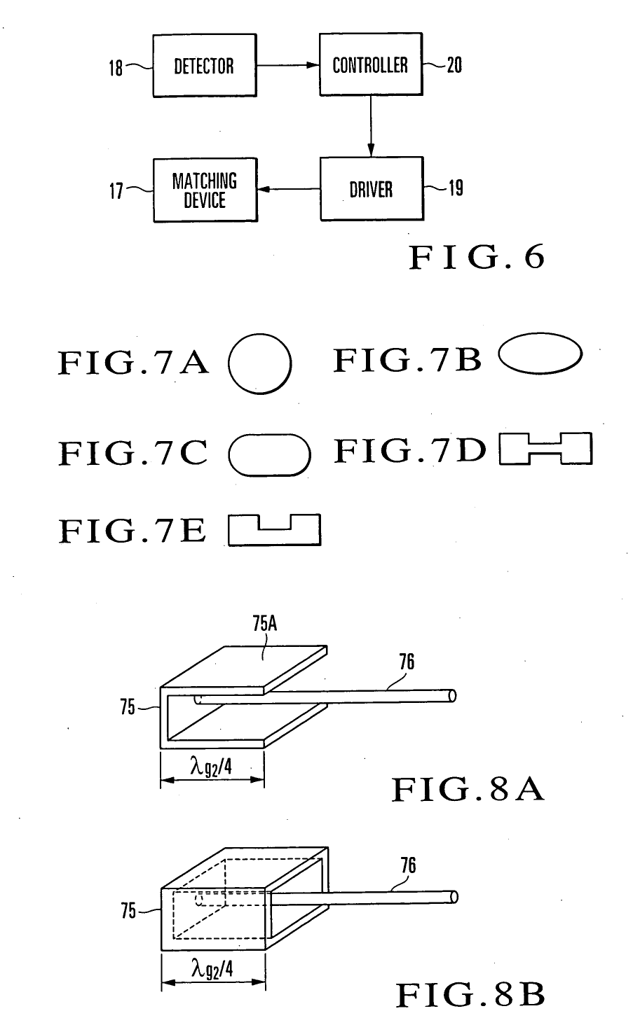

FIG. 2 is a view showing the mechanical arrangement of the electromagnetic field supply apparatus. That is, FIG. 2 shows a sectional arrangement including the axis (Z) of a cylindrical waveguide having a matching device. FIG. 3 is a view for explaining the matching device and a detector of this electromagnetic field supply apparatus. FIG. 4 is a sectional view, taken along a line IV-IV′, showing the sectional arrangement of the matching device in a plane (X-Y plane) perpendicular to the axis (Z) of the cylindrical waveguide. FIG. 5 is a sectional view, taken along a line V-V′ in FIG. 2, showing the sectional arrangement of the detector in a plane (X-Y plane) perpendicular to the axis (Z) of the cylindrical waveguide. FIG. 6 is a block diagram showing the configuration of a control system of the electromagnetic field supply apparatus.

As shown in FIG. 2, the electromagnetic supply apparatus has a high-frequency power supply 11 for generating a microwave having a predetermined frequency of, e.g., 1 GHz to ten-odd GHz, a rectangular waveguide 12 whose transmission mode is TE₁₀, a rectangle-cylinder converter 13 for converting the transmission mode from TE₁₀ to TE₁₁, a cylindrical waveguide 14 whose transmission mode is TE₁₁, and the RLSA 15.

The RLSA 15 is made up of two circular parallel conductor plates 52 and 53 forming a radial waveguide 51, and a conductor ring 54 which shields the two conductor plates 52 and 53 by connecting their outer circumferential portions. A hole 55 connected to the cylindrical waveguide 14 is formed in a central portion of the conductor plate 52 as the upper surface of the radial waveguide 51. A microwave is supplied into the radial waveguide 51 through the hole 55. In the conductor plate 53 as the lower surface of the radial waveguide 51, a plurality of slots 56 for supplying the microwave, which propagates in the radial waveguide 51, into the processing vessel 1 are formed.

A bump 57 is formed in a central portion of the conductor plate 53. The bump 57 is formed into a substantially conical shape which projects toward the hole 55 in the conductor plate 52, and the point of the cone is rounded into a spherical shape. The bump 57 can be made of either a conductor or dielectric material. It is possible by the bump 57 to reduce a change in impedance from the cylindrical waveguide 14 to the radial waveguide 51, and control the reflection of the microwave in the connecting portion between the cylindrical waveguide 14 and radial waveguide 51. A dielectric material having a relative dielectric constant of 1 or more may also be placed in the radial waveguide 51.

The cylindrical waveguide 14 has a circularly polarized wave converter 16, detectors (detecting means) 18, and a matching device 17 arranged in this order from the rectangle-cylinder converter 13 to the RLSA 15.

The circularly polarized wave converter 16 converts the TE₁₁-mode microwave propagating in the cylindrical waveguide 14 into a circularly polarized wave, i.e., into a rotating electric field whose field vector rotates once in one period in a plane perpendicular to the direction of travel. For example, the circularly polarized wave converter 16 is made up of a pair or a plurality of pairs of columnar projections opposing each other on the inner wall surface of the cylindrical waveguide 14.

The matching device 17 matches the impedances of the supply side (i.e., the high-frequency power supply 11) and the load side (i.e., the RLSA 14) of the cylindrical waveguide 14. The matching device 17 is characterized by using branched waveguides connected as reactance elements to the cylindrical waveguide 14. The reactance of the branched waveguides can be changed by a driver 19 shown in FIG. 6.

The detectors 18 have probes 18A projecting in the radial direction from the inner wall surface of the cylindrical waveguide 14. That is, a set of three probes 18A are arranged at an interval of, e.g., substantially ⅛ a guide wavelength λg1 in the direction of the axis (Z) of the cylindrical waveguide 14, and four sets are arranged at an angular interval of 90° in the circumferential direction of the cylindrical waveguide 14; a total of twelve probes 18A are arranged. In the coordinate system, two sets of detectors 18 oppose each other in the X-Z plane, and two sets of detectors 18 oppose each other in the Y-Z plane. Note that three or more detectors 18 may also be arranged at an interval other than an N/2 multiple (N is a natural number) of the guide wavelength λg1 in the direction of the axis (Z) of the cylindrical waveguide 14, or three or more detectors 18 may also be arranged at an angular interval of 45° in the circumferential direction of the cylindrical waveguide 14. It is also possible to arrange three detectors 18 in the X-Z plane and three detectors 18 in the Y-Z plane, i.e., a total of six detectors 18. Each detector 18 performs square-law detection on the microwave power, extracted by its probe 18A, in the cylindrical waveguide 14, and outputs the detection result to a controller 20 shown in FIG. 6.

On the basis of the output signal from each detector 18, the controller 20 controls the driver 19 so as to match the impedances of the supply side and load side of the cylindrical waveguide 14, thereby adjusting the reactance of the branched waveguides of the matching device 17.

The matching device 17 will be described in more detail below with reference to FIGS. 2 to 4, 7A to 7E, and 8A and 8B. FIGS. 7A to 7E are views showing the sectional shapes of the branched waveguides. FIGS. 8A and 8B are perspective views showing examples of the arrangement of a short-circuit plate.

The matching device 17 is made up of a plurality of branched waveguides connected perpendicularly to the direction of the axis (Z) of the cylindrical waveguide 14. More specifically, as shown in FIGS. 2 and 4, three branched waveguides (first branched waveguides) 71A to 71C are equally spaced in the direction of the axis (Z) of the cylindrical waveguide 14, three branched waveguides (third branched waveguides) 72A to 72C oppose the three branched waveguides 71A to 71C, three branched waveguides (second branched waveguides) 73A to 73C are arranged in positions which make an angle of 90° with the positions of the three branched waveguides 71A to 71C, when viewed from the axis (Z) of the cylindrical waveguide 14, and equally spaced in the direction of the axis (Z) of the cylindrical waveguide 14, and three branched waveguides (fourth branched waveguides) 74A to 74C (the branched waveguides 74B and 74C are not shown) oppose the three branched waveguides 73A to 73C. In the coordinate system, the branched waveguides 71A to 71C and 72A to 72C oppose each other in the X-Z plane, and the branched waveguides 73A to 73C and 74A to 74C oppose each other in the Y-Z plane.

The branched waveguides 71A to 71C and 72A to 72C in the X-Z plane and the branched waveguides 73A to 73C and 74A to 74C in the Y-Z plane are alternately arranged in the direction of the axis (Z) of the cylindrical waveguide 14. That is, these branched waveguides are arranged in the order of the branched waveguides 71A and 72A, branched waveguides 73A and 74A, branched waveguides 71B and 72B, branched waveguides 73B and 74B, branched waveguides 71C and 72C, and branched waveguides 73C and 74C from above. With this arrangement, the openings of the waveguides 71A to 74C formed in the inner wall surface of the cylindrical waveguide 14 continue in the same plane, and this prevents an increase in axial ratio of the circularly polarized wave or a decrease in strength of the cylindrical waveguide 14. The same effect can be obtained when all the branched waveguides 71A to 71C and 72A to 72C in the X-Z plane and all the branched waveguides 73A to 73C and 74A to 74C in the Y-Z plane are arranged in different regions in the direction of the axis (Z) of the cylindrical waveguide 14, e.g., when the former and latter are arranged in upper and lower regions, respectively.

As the branched waveguides 71A to 74C, it is possible to use, instead of a rectangular waveguide whose section perpendicular to the axis is a rectangle, a cylindrical waveguide having a circular section as shown in FIG. 7A, a waveguide having an elliptic section as shown in FIG. 7B, a waveguide having a rectangular section with round corners as shown in FIG. 7C, or a ridge waveguide having a ridge in its central portion as shown in FIG. 7D or 7E.

Each of the branched waveguides 71A to 74C has one end which opens in the cylindrical waveguide 14 as described above, and the other end which is electrically functionally short-circuited by a short-circuit plate 75. As shown in FIG. 8A, the short-circuit plate 75 has a U-shape, when viewed from the side, having upper and lower ends bent at right angles, and is inserted into each of the branched waveguides 71A to 74C such that a portion (to be referred to as a bent portion hereinafter) 75A which is bent points in a direction opposite to the opening end of the cylindrical waveguide 14. When the length of the bent portion 75A of the short-circuit plate 75 is set to substantially ¼ a guide wavelength λg2 of the branched waveguides 71A to 74C and an insulating sheet is adhered to form a so-called choke structure, flexibility can be imparted while the reflection of a microwave in the position of the short-circuit plate 75 is ensured. Note that the short-circuit plate 75 may also be given a boxy shape as shown in FIG. 8B by bending the upper, lower, left, and right ends at the right angle.

The short-circuit plate 75 is attached to the end of a rod 76 extending in the direction of the axis (X or Y) of the branched waveguides 71A to 74C. By moving the rod 76 parallel to the direction of the axis (X or Y) of the branched waveguides 71A to 74C by the driver 19 shown in FIG. 6, the short-circuit plate 75 can be freely slid in the branched waveguides 71A to 74C.

The reactance of the branched waveguides 71A to 74C changes in accordance with an electrical length which is a value obtained by dividing the length from one end to the other of the branched waveguide by the guide wavelength λg2. Accordingly, by changing this electrical length by sliding the short-circuit plate 75 which forms the other end of each of the branched waveguides 71A to 74C, the reactance of the branched waveguides 71A to 74C can be changed from a sufficiently large − (minus) value to a sufficiently large + (plus) value via 0 (zero).

As shown in FIG. 3, the intervals between the branched waveguides 71A to 71C, 72A to 72C, 73A to 73C, and 74A to 74C in the direction of the axis (Z) of the cylindrical waveguide 14 are substantially ¼ the guide wavelength λg1 of the cylindrical waveguide 14. Therefore, by changing the reactance of the branched waveguides 71A to 74C from 0 (zero) to sufficiently large +/− values, the matching region of the matching device 17 can be the whole region of a Smith chart. Even when the intervals between the branched waveguides 71A to 71C are substantially ⅛ the guide wavelength λg1, the matching region can be the whole region of a Smith chart. Accordingly, even when the reflected wave from the load is large, impedance matching can be performed at all phases.

Also, the branched waveguides 71A to 74C have no members, such as stabs 1071A to 1074C, which project into the cylindrical waveguide 14, so those arranged in the X-Z plane and those arranged in the Y-Z plane do not interfere with each other and hence do not affect the reactance. Therefore, the reactance of the branched waveguides 71A to 74C substantially changes in the form of a tangent function in accordance with the electrical length based on the length from one end to the other of each branched waveguide. Consequently, even when the reflected wave from the load is large, a desired reactance can be readily realized. This facilitates accurate control of impedance matching.

Furthermore, since the branched waveguides 71A to 74C have no members, such as the stabs 1071A to 1074C, which project into the cylindrical waveguide 14, no discharge occurs between the branched waveguides 71A to 71C and branched waveguides 72A to 72C opposing each other or between the branched waveguides 73A to 73C and branched waveguides 74A to 74C opposing each other, even when the reflected wave from the load is large.

Note that by using only the branched waveguides 71A to 71C, only the branched waveguides 71A to 71C and branched waveguides 72A and 72C opposing each other in the X-Z plane, or only the branched waveguides 71A to 71C in the X-Z plane and the branched waveguides 73A to 73C in the Y-Z plane, the matching region can be the whole region of a Smith chart, and impedance matching can be performed at all phases. However, when the branched waveguides 71A to 71C and 72A to 72C are arranged in the X-Z plane and the branched waveguides 73A to 73C and 74A to 74C are arranged in the Y-Z plane, thereby giving axial symmetry to these branched waveguides, the axial ratio of the circularly polarized wave propagating in the cylindrical waveguide 14 can be brought as near as possible to 1.

Note also that even when three or more branched waveguides are arranged in the direction of the axis (Z) of the cylindrical waveguide 14, impedance matching can be performed at all phases by setting the intervals between these branched waveguides to substantially ¼ or ⅛ the guide wavelength λg1.

Furthermore, even when the intervals between the branched waveguides arranged in the direction of the axis (Z) are not equal, impedance matching can be performed at all phases. For example, it is possible to set the interval between the branched waveguides 71A and 71B to substantially ¼ the guide wavelength λg1, and the interval between the branched waveguides 71B and 71C to substantially ⅛ the guide wavelength λg1.

On the other hand, the matching region narrows if the number of the branched waveguides arranged in the direction of the axis (Z) is two, or if the intervals between the branched waveguides arranged in the direction of the axis (Z) of the cylindrical waveguide 14 take values except for N/2, ¼, and ⅛ of the guide wavelength λg1. However, this arrangement can also be used depending on the conditions.

The operation of the plasma processing apparatus shown in FIGS. 1 and 2 will be described below.

The high-frequency power supply 11 is driven to generate a microwave. This microwave is guided in the TE₁₀ mode by the rectangular waveguide 12, converted into the TE₁₁ mode by the rectangle-cylinder converter, circularly polarized by the circularly polarized wave converter 16 of the cylindrical waveguide 14, introduced to the radial waveguide 51, and supplied into the processing vessel 1 from the plurality of slots 56 formed in the conductor plate 53 which forms the lower surface of the radial waveguide 51. In the processing vessel 1, a plasma gas introduced from the nozzle 6 is ionized, or dissociated in some cases, by the electromagnetic field of the microwave, thereby generating a plasma and processing the substrate 4.

At the same time, each of the plurality of detectors 18 of the cylindrical waveguide 14 extracts a portion of the microwave power in the cylindrical waveguide 14 along the X-Z plane and Y-Z plane, performs square-law detection on the extracted power, and outputs the result to the controller 20. The controller 20 obtains |Γ| cos θ and |Γ| sin θ from the output signal from each detector 18. |Γ| is the absolute value of the reflection coefficient of the load, and 0 is the phase angle of the reflection coefficient of the load. The controller 20 calculates the impedance of the load on the basis of the obtained |Γ| cos θ and |Γ| sin θ, obtains the conditions of impedance matching between the supply side and load side, and determines the moving amount of the short-circuit plates 75 of the branched waveguides 71A to 74C forming the matching device 17. For example, a voltage having a reflection coefficient value (e.g., when a voltage-to-standing wave ratio VSWR is 1.1, |Γ₀|=0.048) is set in the controller 20 beforehand, the moving amount of the short-circuit plates 75 is so determined that the voltage of the detected |Γ| is equal to or lower than the voltage of the preset |Γ₀|. This moving amount is common to all the branched waveguides 71A to 74C. The controller 20 moves the short-circuit plates 75 by controlling the driver 19, thereby performing impedance matching.

In this embodiment, the reactances of all the branched waveguides 71A to 74C are equally adjusted on the basis of the outputs from all the detectors 18. However, it is also possible to adjust the reactances of the branched waveguides 71A to 71C and 72A to 72C in the X-Z plane on the basis of the outputs from the detectors 18 in the X-Z plane, and adjust the reactances of the branched waveguides 73A to 73C and 74A to 74C on the basis of the outputs from the detectors 18 in the Y-Z plane. In the latter case, the moving amount of the short-circuit plates 75 of the branched waveguides 71A to 71C and 72A to 72C in the X-Z plane may be different from that of the short-circuit plates 75 of the branched waveguides 73A to 73C and 74A to 74C in the Y-Z plane.

As an example of a method of obtaining impedance matching conditions by equally spacing a plurality of detectors and processing the output signals from these detectors, a four-probe method is described in, e.g., “Bun'ichi Oguchi and Masamitsu Ohta, ‘Microwave•Milliwave Measurements’, Corona, pp. 84-85”.

Accordingly, even when a wave reflected in the processing vessel 1 or in the radial waveguide 51 enters the cylindrical waveguide 14, this wave can be reflected toward the radial waveguide 51 by the matching device 17, so the reflected wave from the radial waveguide 51 can be canceled by the reflected wave from the matching device 17. This makes it possible to reduce the reflected wave propagating in the cylindrical waveguide 14, and prevents the axial ratio of the circularly polarized wave from increasing owing to the influence of the reflected wave. Accordingly, the field strength distribution in the radial waveguide 51 can be made symmetrical with respect to the axis (Z) of the cylindrical waveguide 14 on time average. As a consequently, an electromagnetic field having this time-average, axially symmetrical distribution can be supplied into the processing vessel 1 from the plurality of slots formed in the conductor plate 53 as the lower surface of the radial waveguide 51, thereby generating a highly uniform plasma.

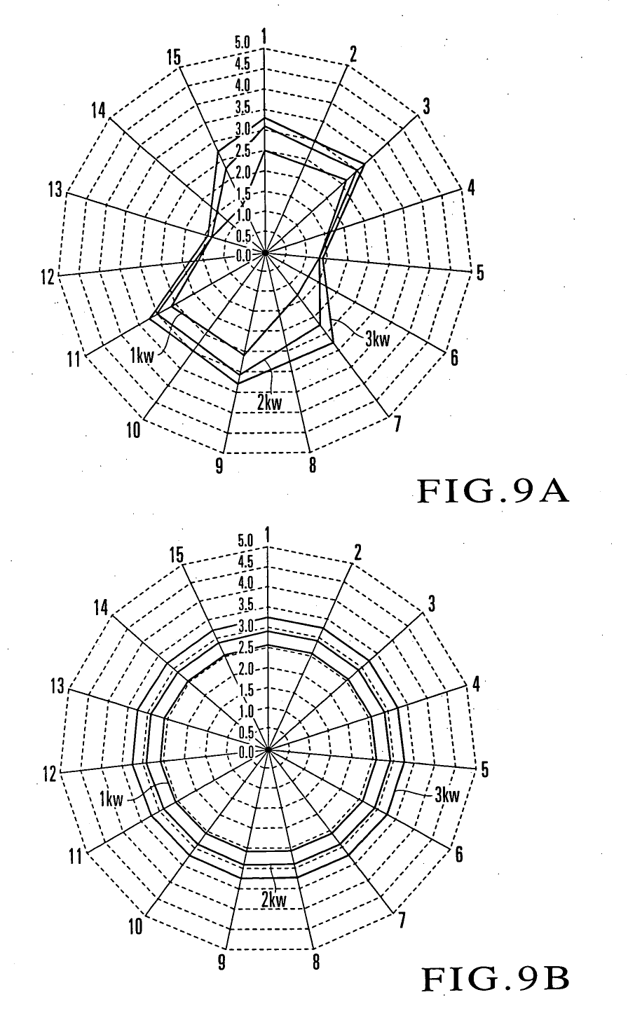

The results of an experiment of the matching device 17 will be described below with reference to FIGS. 9A and 9B.

In this experiment, voltage distributions in the plane (X-Y plane) perpendicular to the axis (Z) of the cylindrical waveguide when the output microwave from the high-frequency power supply 11 was converted into a circularly polarized wave and supplied to the RLSA 15 via the cylindrical waveguide 14 were checked by using the matching device 17 and without using it. More specifically, the inner diameter of the cylindrical waveguide 14 was set to φ90 [mm], rectangular waveguides having dimensions of inner diameter 80 [mm]×27 [mm] were used as the branched waveguides 71A to 74C, the intervals (in the direction of the axis (Z) of the cylindrical waveguide 14) between these rectangular waveguides were set to (λg1)/4, and microwaves having a frequency of 2.45 [GHz] and power values of 1, 2, and 3 [kW] were converted into circularly polarized waves and supplied to a load having VSWR 3.0 (when no matching was performed).

As a consequence, the voltage distributions when the matching device 17 was not used were largely distorted as shown in FIG. 9A. This means that the circularly polarized wave propagating in the cylindrical waveguide 14 was distorted to increase the axial ratio. In contrast, the voltage distributions when the matching device 17 was used were less distorted as shown in FIG. 9B. This means that the axial ratio of the circularly polarized wave propagating in the cylindrical waveguide 14 was close to 1. The above experimental results indicate that the use of the matching device 17 makes it possible to bring the axial ratio of the circularly polarized wave close to 1, and thereby generate a highly uniform plasma on time average in the processing vessel 1.

### Second Embodiment

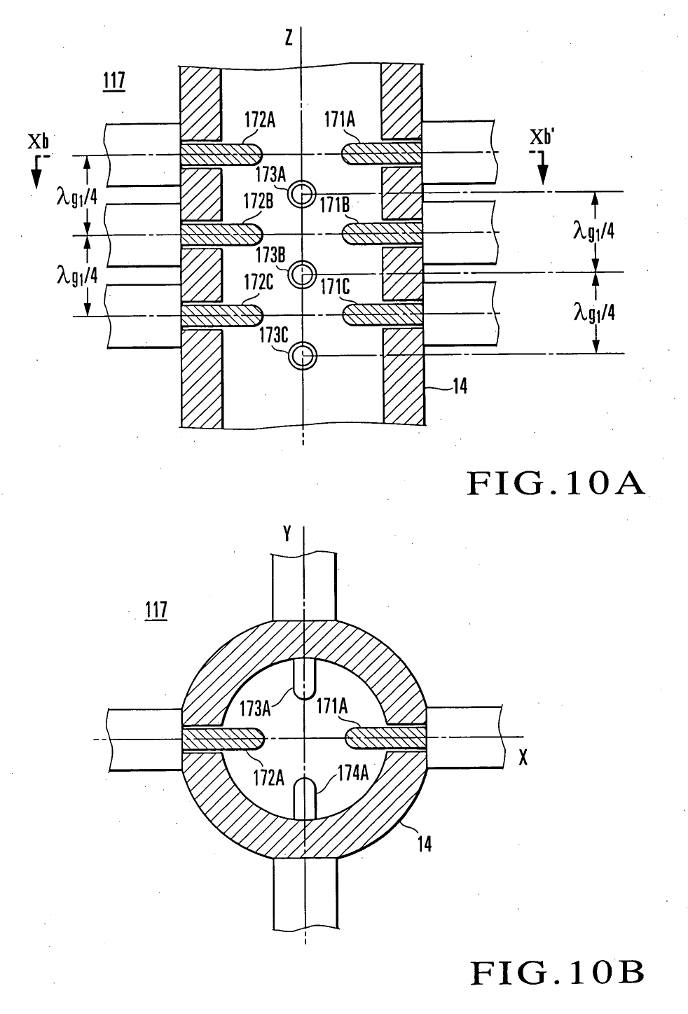

FIG. 10A is a sectional view showing the arrangement of a matching device of the second embodiment of the present invention, and shows a sectional arrangement including the axis (Z) of a cylindrical waveguide having this matching device. FIG. 10B is a sectional view, taken along a line Xb-Xb′ in FIG. 10A, showing a sectional arrangement in a plane (X-Y plane) perpendicular to the axis (Z) of the cylindrical waveguide. The same reference numerals as in FIGS. 2 and 4 denote the same parts in FIGS. 10A and 10B, and an explanation thereof will be suitably omitted.

A matching device 117 shown in FIGS. 10A and 10B match the impedances of the supply side and load side of a cylindrical waveguide 14, and uses a plurality of stabs 171A to 171C, 172A to 172C, 173A to 173C, and 174A to 174C (the stabs 174B and 174C are not shown) as reactance elements. Each of the stabs 171A to 174C is a rod having a circular section and a tip rounded into a substantially spherical shape, and made of a metal such as copper or aluminum.

The stabs 171A to 174C are arranged as follows. That is, the three stabs (first stabs) 171A to 171C are equally spaced in the direction of the axis (Z) of the cylindrical waveguide 14, the three stabs (third stabs) 172A to 172C oppose the three stabs 171A to 171C, the three stabs (second stabs) 173A to 173C are arranged in positions which make an angle of 90° with the positions of the three stabs 171A to 171C, when viewed from the axis (Z) of the cylindrical waveguide 14, and equally spaced in the direction of the axis (Z) of the cylindrical waveguide 14, and the three stabs (fourth stabs) 174A to 174C oppose the three stabs 173A to 173C. In the coordinate system, the stabs 171A to 171C and stabs 172A to 172C oppose each other in the X-Z plane, and the stabs 173A to 173C and stabs 174A to 174C oppose each other in the Y-Z plane.

The stabs 171A to 171C and 172A to 172C in the X-Z plane and the stabs 173A to 173C and 174A to 174C in the Y-Z plane are alternately arranged in the direction of the axis (Z) of the cylindrical waveguide 14. That is, these stabs are arranged in the order of the stabs 171A and 172A, stabs 173A and 174A, stabs 171B and 172B, stabs 173B and 174B, stabs 171C and 172C, and stabs 173C and 174C from above. Therefore, the stabs 171A and 172A and stabs 173A and 174A, stabs 171B and 172B and stabs 173B and 174B, and stabs 171C and 172C and stabs 173C and 174C are arranged in different planes perpendicular to the axis (Z) of the cylindrical waveguide 14.

The tips of the stabs 171A to 174C project in the radial direction from the inner wall surface of the cylindrical waveguide 14, and the length of projection of these tips of the stabs 171A to 174C from the inner wall surface can be freely changed by a driver (not shown). Accordingly, the reactance which is determined by the projection length of the stabs 171A to 174C can be changed from 0 (zero) to a sufficiently large value.

The intervals between the stabs 171A to 171C, 172A to 172C, 173A to 173C, and 174A to 174C in the direction of the axis (Z) of the cylindrical waveguide 14 are substantially ¼ a guide wavelength λg1 of the cylindrical waveguide 14. Therefore, by changing the reactance of the stabs 171A to 174C from 0 (zero) to a sufficiently large value, the matching region of the matching device 117 can be a considerable range at all phases of a Smith chart. Even when the intervals between the stabs 171A to 171C or the like are substantially ⅛ the guide wavelength λg1, the matching region can be a wide region of a Smith chart. Accordingly, even when the reflected power from the load is large, impedance matching can be performed at all phases.

As in the first embodiment, it is also possible to use detectors for detecting the internal voltage of the cylindrical waveguide 14, and a controller for controlling the driver on the basis of output signals from the detectors, thereby changing the projection length of the stabs 171A to 174C. With this arrangement, the control of impedance matching can be automated.

The matching device 117 is made up of the stabs 171A to 174C, and the projection length of the stabs 171A to 174C must be increased if the reflected wave is large and so the reactance must be increased. Since the stabs 171A to 171C and 172A to 172C in the X-Z plane and the stabs 173A to 173C and 174A to 174C in the Y-Z plane are alternately arranged in the direction of the axis (Z) of the cylindrical waveguide 14, the distance between the stabs in the direction of the axis (Z) of the cylindrical waveguide 14 is larger than when the former and latter are arranged in the same plane. This makes it possible to reduce changes in reactance caused by mutual interference produced when the projection length of the stabs 171A to 171C and 172A to 172C in the X-Z plane and the stabs 173A to 173C and 174A and 174C in the Y-Z plane is increased. Accordingly, even when the reflected wave from the load is large, a desired reactance can be realized more easily than in the conventional matching devices. This makes accurate control of impedance matching easier than in the conventional matching devices.

Note that by using only the stabs 171A to 171C in the X-Z plane and the stabs 173A to 173C in the Y-Z plane, the matching region can be a wide region of a Smith chart, and impedance matching can be performed at all phases. However, when the stabs 171A to 171C and 172A to 172C are arranged in the X-Z plane and the stabs 173A to 173C and 174A to 174C are arranged in the Y-Z plane, thereby giving axial symmetry to these stabs, the axial ratio of a circularly polarized wave propagating in the cylindrical waveguide 14 can be brought as near as possible to 1.

Note also that even when three or more stabs are arranged in the direction of the axis (Z) of the cylindrical waveguide 14, impedance matching can be performed at all phases by setting the intervals between these stabs to substantially ¼ or ⅛ the guide wavelength λg1.

Furthermore, even when the intervals between the stabs arranged in the direction of the axis (Z) are not equal, impedance matching can be performed at all phases. For example, it is possible to set the interval between the stabs 171A and 171B to substantially ¼ the guide wavelength λg1, and the interval between the stabs 171B and 171C to substantially ⅛ the guide wavelength λg1.

On the other hand, the matching region narrows if the number of the stabs arranged in the direction of the axis (Z) is two, or if the intervals between the stabs arranged in the direction of the axis (Z) of the cylindrical waveguide 14 take values except for N/2, ¼, and ⅛ of the guide wavelength λg1. However, this arrangement can also be used depending on the conditions.

Note that it is naturally possible to generate a highly uniform plasma by applying the matching device 117 shown in FIGS. 10A and 10B to a plasma processing apparatus as in the first embodiment.

### Third Embodiment

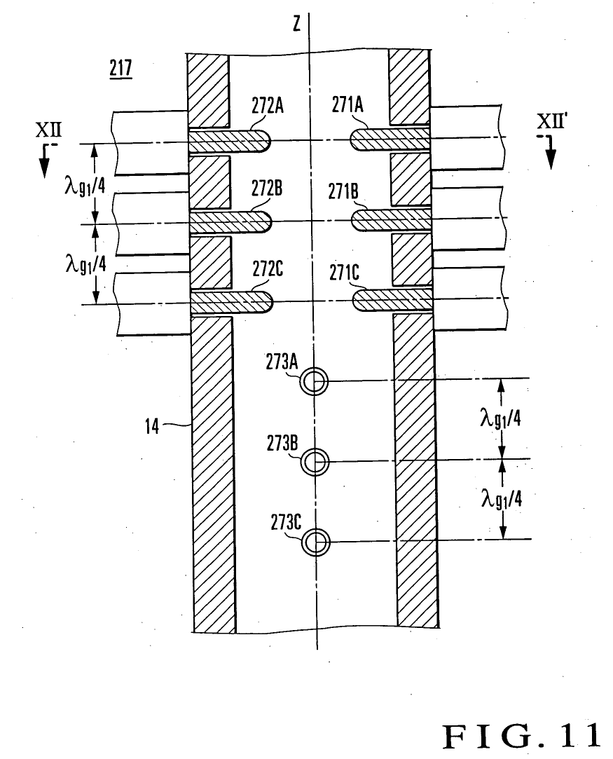

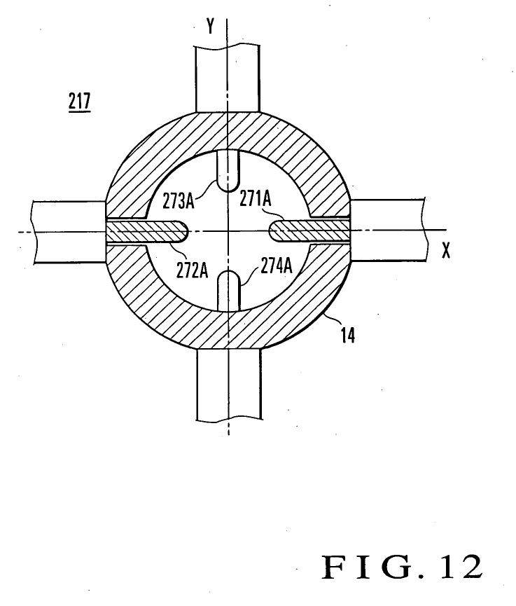

FIG. 11 is a sectional view showing the arrangement of a matching device of the third embodiment of the present invention, and shows a sectional arrangement including the axis (Z) of a cylindrical waveguide having this matching device. FIG. 12 is a sectional view, taken along a line XII-XII′ in FIG. 11, showing a sectional arrangement in a plane (X-Y plane) perpendicular to the axis (Z) of the cylindrical waveguide. The same reference numerals as in FIGS. 2 and 4 denote the same parts in FIGS. 11 and 12, and an explanation thereof will be suitably omitted.

Similar to the matching device 117 shown in FIGS. 10A and 10B, a matching device 217 shown in FIGS. 11 and 12 is made up of stabs (first stabs) 271A to 271C, stabs (third stabs) 272A to 272C, stabs (second stabs) 273A to 273C, and stabs (fourth stabs) 274A to 274C (the stabs 274B and 274C are not shown).

The matching device 217, however, differs from the matching device 117 shown in FIGS. 10A and 10B in that all the stabs 271A to 271C and 272A to 272C in the X-Z plane and all the stabs 273A to 273C and 274A to 274C in the Y-Z plane are arranged in different regions in the direction of the axis (Z) of a cylindrical waveguide 14. That is, in the matching device 217 shown in FIG. 11, the former and latter are separately arranged in the upper and lower regions, respectively, of the cylindrical waveguide 14. Even in this way, the stabs 271A and 272A and stabs 273A and 274A, stabs 271B and 272B and stabs 273B and 274B, and stabs 271C and 272C and stabs 273C and 274C are arranged in different planes perpendicular to the axis (Z) of the cylindrical waveguide 14. Therefore, compared to a case in which the stabs 271A to 271C and 272A to 272C in the X-Z plane and the stabs 273A to 273C and 274 in the Y-Z plane are arranged in the same plane, the distance between the stabs in the direction of the axis (Z) of the cylindrical waveguide 14 increases, so changes in reactance caused by mutual interference of the former and latter can be reduced. This makes accurate control of impedance matching easier than in the conventional matching devices. Accordingly, a highly uniform plasma can be generated by applying the matching device 217 shown in FIG. 11 to a plasma processing apparatus as in the first embodiment.

The rest is the same as the matching device 117 shown in FIGS. 10A and 10B.

### Fourth Embodiment

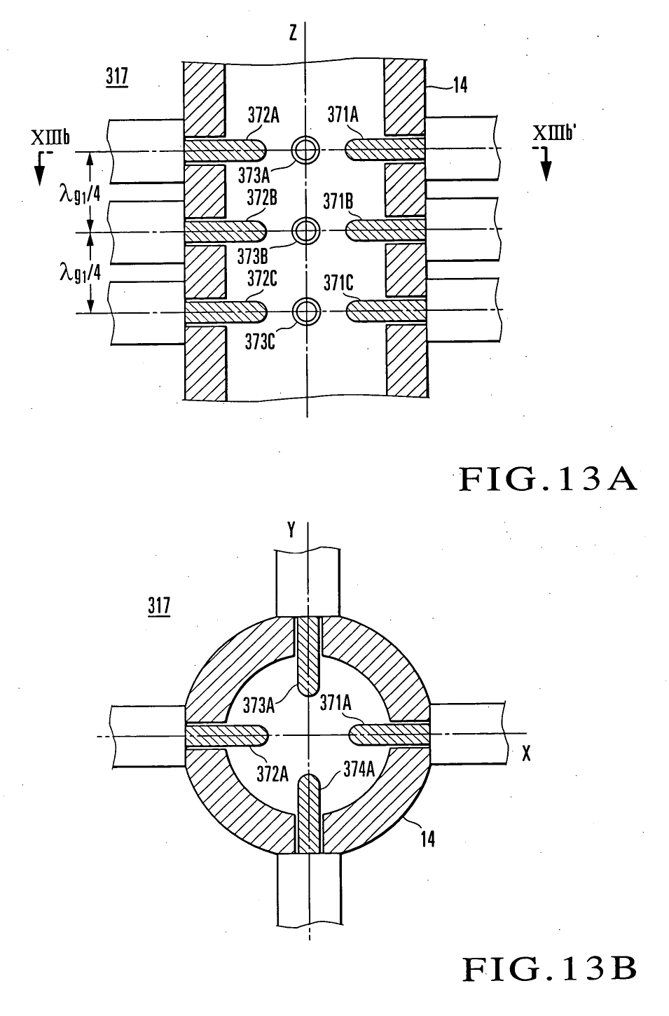

FIG. 13A is a sectional view showing the arrangement of a matching device of the fourth embodiment of the present invention, and shows a sectional arrangement including the axis (Z) of a cylindrical waveguide having this matching device. FIG. 13B is a sectional view, taken along a line XIIIb-XIIIb′ in FIG. 13A, showing a sectional arrangement in a plane (X-Y plane) perpendicular to the axis (Z) of the cylindrical waveguide. The same reference numerals as in FIGS. 2 and 4 denote the same parts in FIGS. 13A and 13B, and an explanation thereof will be suitably omitted.

Similar to the matching device 117 shown in FIGS. 10A and 10B, a matching device 317 shown in FIGS. 13A and 13B is made up of stabs (first stabs) 371A to 371C, stabs (third stabs) 372A to 372C, stabs (second stabs) 373A to 373C, and stabs (fourth stabs) 374A to 374C (the stabs 374B and 374C are not shown).

The matching device 317, however, differs from the matching device 117 shown in FIGS. 10A and 10B in that the stabs 371A to 374C are made of a dielectric material having a relative dielectric constant of 1 or more. The whole or only the tip of each of the stabs 371A to 374C can be made of a dielectric material. When at least the tips of the stabs 371A to 374C are made of a dielectric material, no resonance occurs. Therefore, even when the stabs 371A to 371C and 372A to 372C in the X-Z plane and the stabs 373A to 373C and 374A to 374C in the Y-Z plane are arranged in the same plane as in the conventional matching devices, it is possible to reduce changes in reactance caused by mutual interference produced when the projection length of the former and latter is increased. Also, even when high power is supplied, it is possible to reduce discharge between the tips of the stabs 371A to 374C or between the tips of the stabs 371A to 374C and the inner surface of a cylindrical waveguide 14. Consequently, even if the reflected wave from the load is large, a desired reactance can be realized more easily than in the conventional matching devices. This makes accurate control of impedance matching easier than in the conventional matching devices.

Accordingly, a highly uniform plasma can be generated by applying the matching device 317 shown in FIGS. 13A and 13B to a plasma processing apparatus as in the first embodiment.

Note that at least the tips of the stabs 371A to 374C are desirably made of a material, such as beryllia porcelain, ceramic, or alumina, having a small dielectric loss.

Note also that these stabs made of a dielectric material can be alternately arranged in the X-Z plane and Y-Z plane as shown in FIGS. 10A and 10B, or separately arranged in those regions of the X-Z plane and Y-Z plane, which are different in the Z direction as shown in FIG. 11.

The rest is the same as the matching device 117 shown in FIGS. 10A and 10B.

### Fifth Embodiment

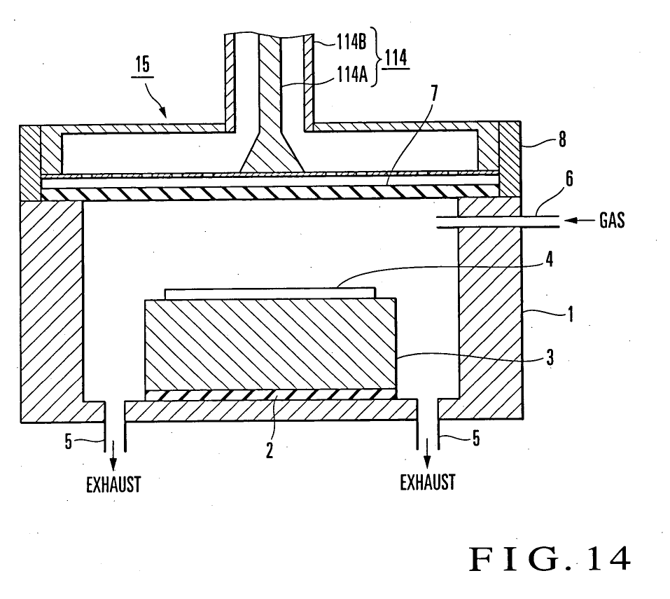

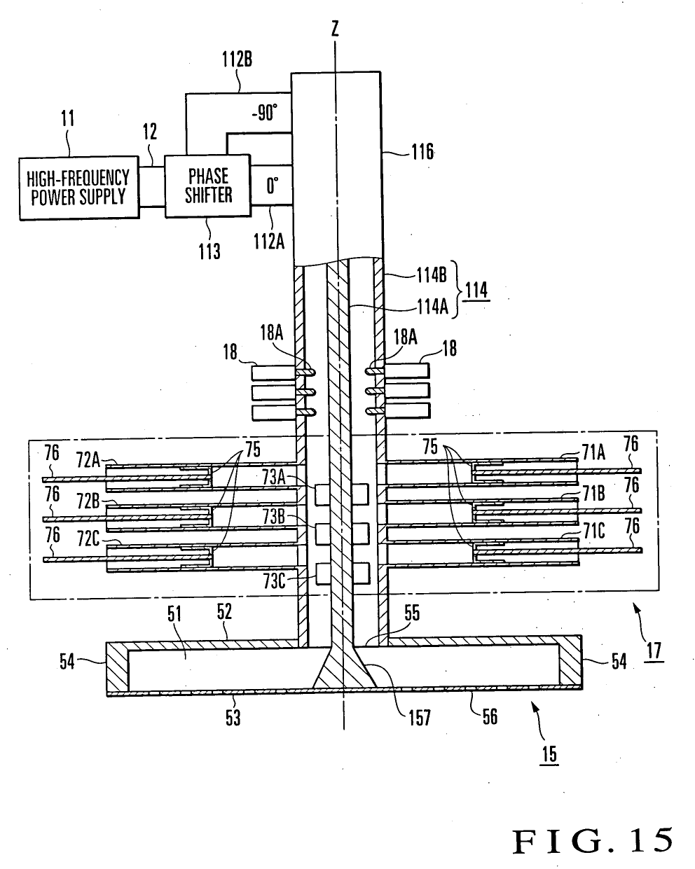

In the above embodiments, only the propagation of a TE₁₁-mode circularly polarized wave electromagnetic field in the cylindrical waveguide 14 is explained. However, the matching device and plasma processing apparatus of the present invention are also applicable to an apparatus in which a TE-mode rotating electromagnetic field propagates in a coaxial waveguide. FIGS. 14 and 15 illustrate an embodiment in which the present invention is applied to this apparatus. FIG. 14 is a sectional view showing the arrangement of a processing vessel of a plasma processing apparatus. FIG. 15 is a view showing the mechanical arrangement of an electromagnetic field supply apparatus of the plasma processing apparatus.

This plasma processing apparatus shown in FIGS. 14 and 15 is the same as the plasma processing apparatus shown in FIGS. 1 and 2 except that a coaxial waveguide 114 is used instead of the cylindrical waveguide 14. Therefore, the same reference numerals as in FIGS. 1 and 2 denote the same parts in FIGS. 14 and 15, and an explanation thereof will be suitably omitted.

As shown in FIG. 15, the coaxial waveguide 114 is made up of a coaxially arranged inner conductor 114A and outer conductor 114B. A rotating electromagnetic field generator 116 is connected to one end of the coaxial waveguide 114. The rotating electromagnetic field generator 116 generates a rotating electromagnetic field of a coaxial waveguide TE mode by connecting, to the outer conductor 114B of the coaxial waveguide 114, two rectangular waveguides 112A and 112B in which microwaves having phases shifted 90° from each other propagate. Referring to FIG. 15, the two rectangular waveguides 112A and 112B are juxtaposed in the direction of the axis (Z) of the coaxial waveguide 114. However, the rectangular waveguides 112A and 112B may also be arranged in positions, in the same plane perpendicular to the axis (Z) of the coaxial waveguide 114, where they make an angle of 90° with the axis (Z). Note that the phase difference between the microwaves propagating in the two rectangular waveguides 112A and 112B can be produced by splitting a microwave supplied from a high-frequency power supply 11 via a rectangular waveguide 12, and delaying one of the split phases by 90° from the other phase by a phase shifter 113.

An RLSA 15 is connected to the other end of the coaxial waveguide 114. More specifically, the other end of the outer conductor 114B of the coaxial waveguide 114 is connected to the circumference of an opening 55 of a conductor plate 52 which is the upper surface of a radial waveguide 51. A bump 157 is connected to the other end of the inner conductor 114A of the coaxial waveguide 114, and the bottom surface of the bump 157 is connected to the center of a conductor plate 53 which is the lower surface of the radial waveguide 51. Note that a dielectric material having a relative dielectric constant of 1 or more may also be placed in the radial waveguide 51.

The coaxial waveguide 114 has detectors 18 and a matching device 17. FIG. 15 shows an example of the matching device 17, similar to the matching device shown in FIG. 2, having branched waveguides each having one end which opens in the outer conductor 114B of the coaxial waveguide 114 and the other end which is electrically functionally short-circuited. However, it is also possible to use the matching devices 117, 217, and 317, as shown in FIGS. 10 to 13, having stabs which project in the radial direction from the inner wall surface of the outer conductor 114B of the coaxial waveguide 114. Regardless of whether the matching device 17, 117, 217, or 317 is used, accurate control of impedance matching can be easily performed while a TE-mode rotating electromagnetic field is propagating in the coaxial waveguide 114. This makes it possible to obtain effects such as easy generation of a highly uniform plasma.

Various embodiments using microwaves have been explained above. However, similar effects can be obtained even when a high frequency containing a frequency band lower than a microwave is used in the matching device and plasma processing apparatus of the present invention.

### Sixth Embodiment

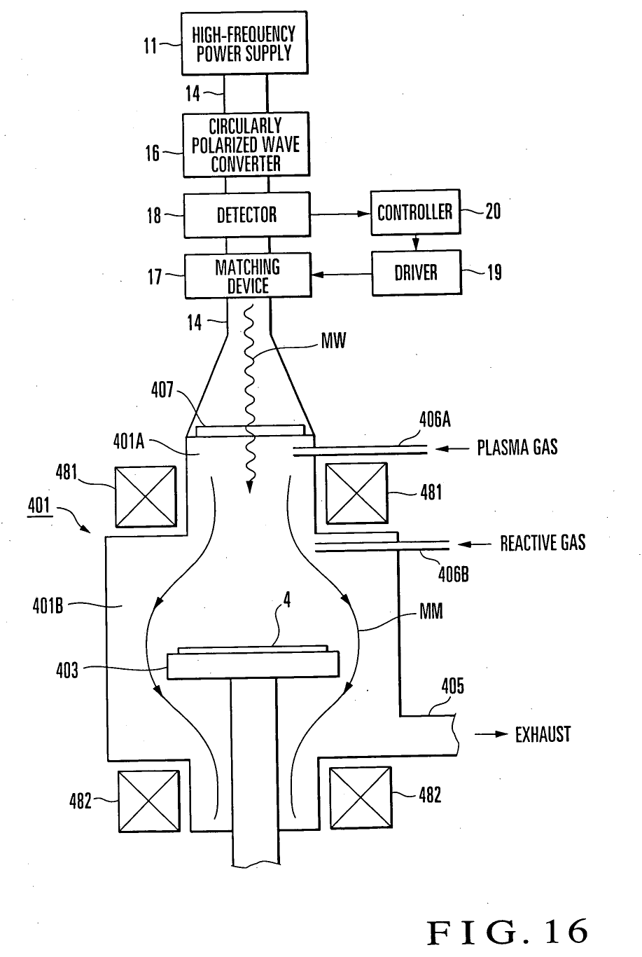

The present invention is applicable not only to the microwave (high-frequency) plasma processing apparatus described above, but also to an electron-cyclotron-resonance (ECR) plasma processing apparatus. FIG. 16 is a view showing an example of the arrangement of an ECR plasma processing apparatus to which the present invention is applied. The same reference numerals as in FIGS. 1, 2, and 6 denote the same parts in FIG. 16, and an explanation thereof will be suitably omitted.

This ECR plasma processing apparatus shown in FIG. 16 has a vessel 401 including a plasma chamber 401A for generating a plasma, and a reaction chamber 401B for performing processing such as plasma CVD.

A main electromagnetic coil 481 for forming a magnetic field having a flux density B of 87.5 mT in the plasma chamber 401A is formed around the outer circumferential surface of the plasma chamber 401A. One end of a cylindrical waveguide 14 is connected to the upper end of the plasma chamber 401A via a dielectric plate 407. The cylindrical waveguide 14 supplies a microwave MW having the same frequency, 2.45 GHz, as the electron-cyclotron frequency (the frequency when electrons in a plasma rotate around a line of magnetic force).

The reaction chamber 401B which communicates with the plasma chamber 401A houses a substrate table 403 on the upper surface of which an Si substrate 4 as an object to be processed is placed. Also, an auxiliary electromagnetic coil 482 is formed below the bottom surface of the reaction chamber 401B. A magnetic field generator made up of the main electromagnetic coil 481 and auxiliary electromagnetic coil 482 forms a mirror magnetic field MM in the reaction chamber 401B.

A nozzle 406A for supplying a plasma gas such as N₂ is formed in the upper portion of the plasma chamber 401A, and a nozzle 406B for supplying a reaction gas such as SiH₄ is formed in the upper portion of the reaction chamber 401B. In addition, an exhaust port 405 which communicates with a vacuum pump is formed in the lower portion of the reaction chamber 401B.

In an arrangement like this, when a magnetic field having a flux density B of 87.5 mT is formed in the plasma chamber 401A and the microwave MW having a frequency of 2.45 GHz is introduced into the plasma chamber 401A, electron-cyclotron resonance occurs, and the energy of the microwave MW efficiently moves to electrons and heats them. These electrons thus heated by the microwave MW allow N₂ ionization in the plasma chamber 401 to continue, thereby generating a plasma.

A high-frequency power supply 11 is connected to the other end of the cylindrical waveguide 14. Also, the cylindrical waveguide 14 has a circularly polarized wave converter 16, detector 18, and matching device 17, a controller 20 is connected to the detector 18, and a driver 19 of the matching device 17 is connected to the controller 20. Since accurate control of impedance matching can be easily performed by the use of the matching device 17 as in the first embodiment, effects such as easy generation of a highly uniform plasma can be obtained. Note that instead of the matching device 17, it is also possible to use the matching device 117 shown in FIGS. 10A and 10B, the matching device 217 shown in FIGS. 11 and 12, or the matching device 317 shown in FIGS. 13A and 13B.

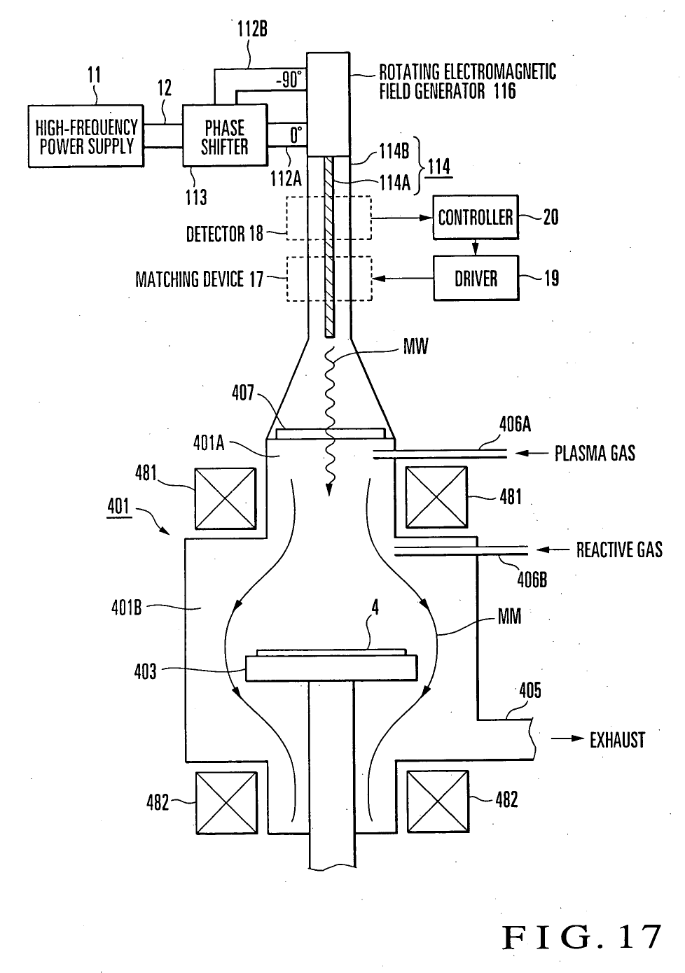

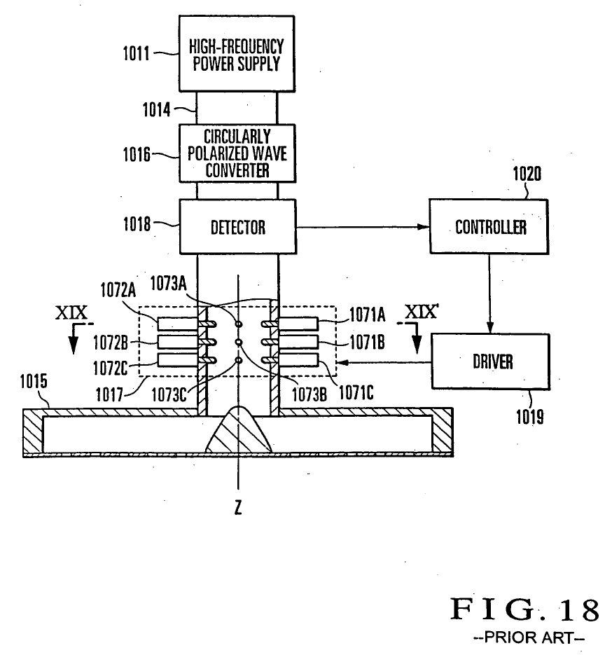

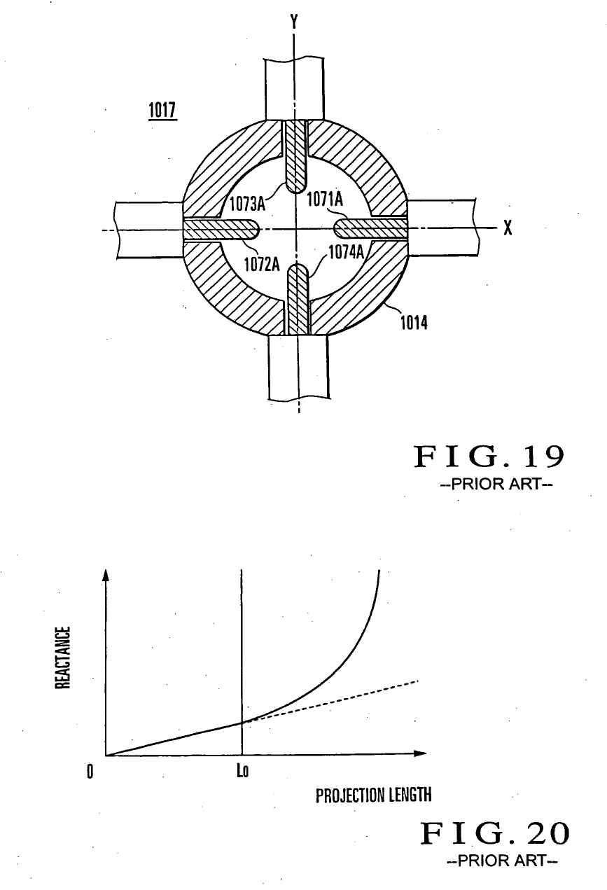

In addition, as shown in FIG. 17, a rotating electromagnetic field of a coaxial waveguide TE mode may also be supplied by using a coaxial waveguide 114 in place of the cylindrical waveguide 14. In FIG. 17, the same reference numerals as in FIGS. 15 and 16 denote the same parts.

### INDUSTRIAL APPLICABILITY

The plasma processing apparatus of the present invention can be used in an etching apparatus, CVD apparatus, ashing apparatus, and the like.

Also, the matching device of the present invention can be used not only in the plasma processing apparatus but also in, e.g., a communication apparatus and high-frequency superheater.

1-22. (canceled)

23. A matching device for matching impedances of a supply side and load side of a cylindrical waveguide or coaxial waveguide, characterized by comprising a plurality of first stabs and a plurality of second stabs which project in a radial direction from an inner wall surface of said cylindrical waveguide or from an inner wall surface of an outer conductor of said coaxial waveguide,
wherein said first stabs are arranged at a predetermined interval in an axial direction of said cylindrical waveguide or coaxial waveguide,
said second stabs are arranged in positions which make an angle of 90° with positions of said first stabs when viewed from an axis of said cylindrical waveguide or coaxial waveguide, and arranged at a predetermined interval in the axial direction of said cylindrical waveguide or coaxial waveguide, and
at least tips of said first and second stabs are made of a dielectric material having a relative dielectric constant of not less than 1.

24. A matching device according to claim 23, characterized by further comprising a plurality of third stabs and a plurality of fourth stabs which project in the radial direction from the inner wall surface of said cylindrical waveguide or from the inner wall surface of the outer conductor of said coaxial waveguide,
wherein said third stabs oppose said first stabs,
said fourth stabs oppose said second stabs, and
at least tips of said first and second stabs are made of a dielectric material having a relative dielectric constant of not less than 1.

25. A matching device according to claim 23, characterized in that the number of said stabs arranged in the axial direction of said cylindrical waveguide or coaxial waveguide is at least three.

26. A matching device according to claim 25, characterized in that an interval between said stabs in the axial direction of said cylindrical waveguide or coaxial waveguide is ¼ or ⅛ a guide wavelength of said cylindrical waveguide or coaxial waveguide.

27. A matching device according to claim 23, characterized in that said stabs are equally spaced in the axial direction of said cylindrical waveguide or coaxial waveguide.

28. A matching device according to claim 23, characterized in that a projection length, which is a length of projection from the inner wall surface of said cylindrical waveguide or from the inner wall surface of the outer conductor of said coaxial waveguide, of said stabs is changeable.

29. A matching device according to claim 28, characterized by further comprising:
detecting means for detecting an internal voltage of said cylindrical waveguide or coaxial waveguide; and
control means for changing the projection length of said stabs on the basis of an output signal from said detecting means.

30. A matching device according to claim 23, characterized in that a TE₁₁-mode circularly polarized wave electromagnetic field progress in said cylindrical waveguide, and a TE-mode rotating electromagnetic field propagates in said coaxial waveguide.

31-32. (canceled)

33. A plasma processing apparatus characterized by comprising:
a processing vessel which accommodates an object to be processed;
a slot antenna which supplies an electromagnetic field into said processing vessel;
a cylindrical waveguide or coaxial waveguide connected between said slot antenna and a high-frequency power supply; and
a matching device attached to said cylindrical waveguide or coaxial waveguide to match impedances of said slot antenna and power supply,
wherein said matching device comprises a plurality of first stabs and a plurality of second stabs which project in a radial direction from an inner wall surface of said cylindrical waveguide or from an inner wall surface of an outer conductor of said coaxial waveguide,
said first stabs are arranged at a predetermined interval in an axial direction of said cylindrical waveguide or coaxial waveguide,
said second stabs are arranged in positions which make an angle of 90° with positions of said first stabs when viewed from an axis of said cylindrical waveguide or coaxial waveguide, and arranged at a predetermined interval in the axial direction of said cylindrical waveguide or coaxial waveguide, and
at least tips of said first and second stabs are made of a dielectric material having a relative dielectric constant of not less than 1.

34-36. (canceled)
